(19) United States
(12) Patent Application Publication
(10) Pub. No.: US 2006/0203871 A1
(43) Pub. Date: Sep. 14, 2006

(54) Nitride semiconductor light emitting device and fabrication method thereof

(75) Inventors: Tetsuzo Ueda, Osaka (JP); Satoshi Nakazawa, Osaka (JP); Toshiyuki Takizawa, Kyoto (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/371,249

(22) Filed: Mar. 9, 2006

(30) Foreign Application Priority Data
Mar. 10, 2005 (JP) 2005-067002

(51) Int. Cl. H01S 5/00

(52) U.S. Cl. 372/43.01

(57) ABSTRACT

A nitride semiconductor light emitting device includes: an active layer formed of a first III-V nitride semiconductor, the active layer having opposite surfaces which face each other; an alloy crystal layer formed of InₓAl_{y}Ga_{1-x-y}N (0<x<1, 0<y<1, 0<x+y<1) on one of the opposite surfaces of the active layer, the alloy crystal layer having n-type conductivity; and an ohmic electrode formed to be in contact with the alloy crystal layer. A transparent electrode is provided on the other surface of the active layer. A p-side electrode is provided on a portion of the transparent electrode.

### CROSS-REFERENCE TO RELATED APPLICATIONS

This application claims priority under 35 U.S.C. §119(a) on Japanese Patent Application No. 2005-67002 filed on Mar. 10, 2005 and Japanese Patent Application No. 2006-59688 filed on Mar. 6, 2006, the entire contents of which are hereby incorporated by reference.

### BACKGROUND OF THE INVENTION

The present invention relates to a nitride semiconductor light emitting device and a fabrication method thereof. Specifically, the present invention relates to a semiconductor light emitting device applicable to, for example, a short-wavelength light emitting diode or a blue-violet semiconductor laser diode and to a fabrication method thereof.

A III-V nitride semiconductor expressed by a general formula, InₓAl_{y}Ga_{1-x-y}N (0≦x≦1, 0≦y≦1, and 0≦x+y≦1), is applicable to a light emitting device, such as a visible-range light emitting diode, a short-wavelength semiconductor laser diode, or the like, because gallium nitride (GaN) has a relatively large energy gap of 3.4 eV at room temperature. Specifically, as for the light emitting diodes, blue light emitting diodes and green light emitting diodes have already been practically used in display panels, large-screen display devices, traffic signals, etc. White light emitting diodes, which emit visible light by excitation of a fluorescent material, have also been commercialized as a light source for a LCD backlight, etc. On the other hand, semiconductor laser diodes of nitride semiconductors are currently at a technology level such that they are practically usable as a light source for writing data in next-generation high-density optical discs typified by Blue-Ray Discs. Thus, researches and developments have been actively conducted for the purpose of achieving higher brightness, higher power and higher efficiency in semiconductor optical devices of III-V nitride semiconductors.

Researches and developments already conducted in the crystal growth techniques where Metal Organic Chemical Vapor Deposition (MOCVD) has been a centerpiece have resulted in great improvements in brightness, power, and emission efficiency in light emitting devices of nitride semiconductors. Specifically, establishment of principal techniques, such as a heteroepitaxial growing technique with a low-temperature buffer layer intervening over a sapphire substrate, an active layer growing technique with a multiquantum well structure of InGaN, a low-resistant p-type GaN growing technique with annealing for activation of dopants, etc., have greatly contributed to the improvement in performance of nitride semiconductor optical devices.

Presently, substrates of gallium nitride (GaN) have been commercially available, and the crystallinity of an epitaxial layer grown over a GaN substrate is expected to further improve. To achieve higher performance in the future, decreasing the contact resistance at an ohmic electrode and reducing the parasitic resistance have been becoming more important.

Hereinafter, a conventional nitride semiconductor light emitting device with a sapphire substrate is described.

FIG. 9 shows a cross-sectional structure of a light emitting diode fabricated using a III-V nitride semiconductor according to a conventional example (see, for example, Japanese Laid-Open Patent Publication No. 6-314822).

The structure of the light emitting diode of the conventional example and a fabrication method thereof are described with reference to FIG. 9. Referring to FIG. 9, first, an n-type contact layer 802 of n-type GaN, an n-type cladding layer 803 of n-type AlGaN, a multiquantum well active layer 804 of InGaN, and a p-type cladding layer 805 of p-type AlGaN are sequentially formed over a sapphire substrate 801 by, for example, MOCVD.

Then, dry etching with chlorine (Cl₂) gas, for example, is selectively carried out on the formed p-type cladding layer 805, the multiquantum well active layer 804 and the n-type cladding layer 803, such that a portion of the n-type contact layer 802 is exposed.

Thereafter, a layered structure is formed of nickel (Ni) and gold (Au) on the upper surface of the p-type cladding layer 805. The layered structure constitutes a transparent electrode 806. To give transparency to the transparent electrode 806, the layered structure needs to have a thickness of 10 nm or less. On the exposed portion of the n-type contact layer 802, a layered structure is formed of titanium (Ti) and aluminum (Al). The layered structure constitutes an n-side electrode 807.

Subsequently, a p-side electrode 808 is formed of gold (Au) on a portion of the transparent electrode 806. The p-side electrode 808 functions as a bonding pad.

Since the transparent electrode 806 is provided in addition to the p-side electrode 808, large part of light emitted from the multiquantum well active layer 804, for example, blue light at an emission wavelength of 470 nm, is transmitted through the transparent electrode 806 and exits the device.

However, according to the conventional nitride semiconductor light emitting device and its fabrication method, the n-side electrode 807, which is an ohmic electrode, is formed on the n-type contact layer 802 of n-type GaN. In general, GaN has a large energy gap of 3.4 eV but has a small electron affinity. Therefore, the potential barrier between GaN and the metal of the ohmic electrode becomes large. Thus, it is difficult to realize a low-resistive ohmic contact. As a result, the ohmic contact resistance for the n-type contact layer 802 remains about 1×10⁻⁵ Ωcm². Therefore, it is extremely difficult to realize an ohmic contact resistance of 1×10⁻⁶ Ωcm² or less, which would be realized by a compound semiconductor device fabricated using another type of III-V compound semiconductor, such as gallium arsenide (GaAs), or the like. Thus, the operation voltage of the light emitting diode fabricated using a III-V nitride semiconductor cannot be readily decreased.

### SUMMARY OF THE INVENTION

In view of the above problems, an objective of the present invention is to provide a semiconductor light emitting device fabricated using a III-V nitride compound semiconductor wherein the ohmic contact resistance for an n-type semiconductor layer is decreased to enable a low-voltage operation.

To achieve the above objective, according to the present invention, a nitride semiconductor light emitting device uses an alloy crystal layer of n-type InAlGaN, which is a quaternary alloy crystal, as an n-type contact layer on which an ohmic electrode is formed.

The present inventors repeatedly conducted studies on the ohmic contact resistance between an n-type nitride semiconductor layer and an ohmic electrode through various experiments to reach the following knowledge. That is, InAlGaN, which is a quaternary alloy crystal, has an electron affinity greater than that of GaN, and therefore, the difference in work function between InAlGaN and the ohmic electrode becomes smaller. As a result, InAlGaN has a smaller potential barrier in a portion which is in contact with the ohmic electrode, and accordingly, the contact resistance of 1×10⁻⁶ Ωcm² or less is realized.

With the above structure, a smaller ohmic contact resistance is realized as compared with a structure where an ohmic electrode is formed on an n-type GaN layer. Thus, a light emitting device with a low operation voltage can be realized.

Specifically, the first nitride semiconductor light emitting device according to the present invention includes: an active layer formed of a first III-V nitride semiconductor, the active layer having opposite surfaces which face each other; an alloy crystal layer formed of InₓAl_{y}Ga_{1-x-y}N (0<x<1, 0<y<1, 0<x+y<1) on one of the opposite surfaces of the active layer, the alloy crystal layer having n-type conductivity; and an ohmic electrode formed to be in contact with the alloy crystal layer.

In the first nitride semiconductor light emitting device, according to the above-described knowledge, the contact resistance between the n-type alloy crystal layer and the ohmic electrode can be reduced without increasing the n-type doping concentration. Thus, a nitride semiconductor light emitting device with smaller series resistance and capable of reduction in operation voltage can be realized.

Preferably, the first nitride semiconductor light emitting device further includes a substrate and an underlying layer formed of a second III-V nitride semiconductor on the substrate, wherein the alloy crystal layer is lattice-matched with the underlying layer.

With the above feature, the alloy crystal layer lattice-matched with the underlying layer can be formed thick without occurrence of cracks. For example, when a p-side ohmic electrode and an n-side ohmic electrode are formed on one surface, the series resistance around the n-side ohmic electrode is further reduced. Thus, the operation voltage can be further decreased.

In the first nitride semiconductor light emitting device, in the alloy crystal layer, the composition ratio of y to x (y/x) in InₓAl_{y}Ga_{1-x-y}N (0<x<1, 0<y<1, 0<x+y<1) is preferably in the range of 3.5 to 3.7.

With the above feature, the alloy crystal layer is lattice-matched with the underlying nitride semiconductor layer and achieves improved crystallinity.

In the first nitride semiconductor light emitting device, the ohmic electrode preferably has a contact resistance of 1×10⁻⁶ Ωcm² or less.

With the above feature, the contact resistance of the n-side ohmic electrode is sufficiently reduced.

Preferably, the first nitride semiconductor light emitting device further includes a first cladding layer formed of Al_{z}Ga_{1-z}N (0<z≦1) to be in contact with the alloy crystal layer, the first cladding layer having n-type conductivity, wherein in the composition of the alloy crystal layer, the content of Al, Ga or In is gradient such that a lower end of a conduction band is gradual at an interface between the alloy crystal layer and the first cladding layer.

With the above structure where the first cladding layer is formed of Al_{z}Ga_{1-z}N to be in contact with the alloy crystal layer and have n-type conductivity, the first cladding layer contains Al as a constituent and therefore, in general, has a smaller refractive index and larger energy gap as compared with the active layer not containing Al. Accordingly, the light confinement function for light coming in a perpendicular direction from the active layer is improved while the current confinement function is also improved. Further, since the alloy crystal layer of InAlGaN has a gradient composition, the hetero potential barrier between the alloy crystal layer and the first cladding layer of AlGaN is decreased. Thus, a nitride semiconductor light emitting device capable of highly-efficient emission and having a small series resistance can be realized.

Preferably, the first nitride semiconductor light emitting device further includes a first cladding layer formed of Al_{z}Ga_{1-z}N (0<z≦1) to be in contact with the alloy crystal layer, the first cladding layer having n-type conductivity, wherein in the composition of the first cladding layer, the content of Al is gradient such that a lower end of a conduction band is gradual at an interface between the first cladding layer and the alloy crystal layer.

With such a gradient composition of the first cladding layer, the hetero potential barrier between the alloy crystal layer and the first cladding layer can also be reduced. Therefore, a nitride semiconductor light emitting device capable of highly-efficient emission and having a small series resistance can be realized.

Preferably, the first nitride semiconductor light emitting device further includes a second cladding layer formed of a third III-V nitride semiconductor on the other surface of the active layer, the second cladding layer having p-type conductivity; and a metal electrode formed to be in contact with the second cladding layer, the reflectance of the metal electrode at a wavelength of light emitted from the active layer being higher than 70%, wherein the emitted light passes through the alloy crystal layer to exit the light emitting device.

With the above feature, a light emitting diode with improved light extraction efficiency can be realized.

In this case, the metal electrode preferably contains platinum (Pt), silver (Ag) or rhodium (Rh) as a main constituent. The reflectance of these metals for the wavelength of the emitted light is 70% or higher, and therefore, these metals are preferable.

Further, in this case, the first nitride semiconductor light emitting device further includes a metal film formed to be in contact with the metal electrode and have a thickness of 10 μm or more.

With the above feature, the metal film having a thickness of 10 μm or more decreases the thermal resistance and achieves excellent heat radiation property, and thus, a high power operation is enabled.

In this case, the metal film preferably contains gold (Au) as a main constituent.

With the above feature, a metal film with a small thermal resistance can readily be formed by plating.

Preferably, the first nitride semiconductor light emitting device further includes a second cladding layer formed of a third III-V nitride semiconductor on the other surface of the active layer, the second cladding layer having p-type conductivity, wherein the second cladding layer has a striped structure which functions as a waveguide, the striped structure enabling the active layer to cause laser oscillation.

With the above feature, a semiconductor laser diode having a small series resistance and capable of low voltage operation can be realized.

The second nitride semiconductor light emitting device according to the present invention includes: a substrate formed of GaN to have n-type conductivity; a pn junction structure formed on a surface of the substrate, the pn junction structure including an active layer; an alloy crystal layer formed of InₓAl_{y}Ga_{1-x-y}N (0<x<1, 0<y<1, 0<x+y<1) on the other surface of the substrate, the alloy crystal layer having n-type conductivity; and an ohmic electrode formed to be in contact with the alloy crystal layer.

In the second nitride semiconductor light emitting device, the pn junction structure including the active layer, which is formed on a surface of the GaN substrate having n-type conductivity, has excellent crystallinity and therefore can achieve highly-efficient emission. Further, since the alloy crystal layer formed of InₓAl_{y}Ga_{1-x-y}N and having n-type conductivity is formed to be in contact with the other surface of the substrate, according to the above-described knowledge, the contact resistance between the alloy crystal layer and the ohmic contact which is in contact therewith can be decreased. Thus, a nitride semiconductor light emitting device with small series resistance and capable of low voltage operation can be realized.

The third nitride semiconductor light emitting device according to the present invention includes: a substrate formed of InₓAl_{y}Ga_{1-x-y}N (0<x<1, 0<y<1, 0<x+y<1) to have n-type conductivity; a pn junction structure formed to be in contact with the substrate, the pn junction structure including an active layer; and an ohmic electrode formed to be in contact with the substrate.

In the third nitride semiconductor light emitting device, the substrate itself is formed of a quaternary alloy crystal of InₓAl_{y}Ga_{1-x-y}N, and therefore, the contact resistance of the ohmic electrode which is in contact with the substrate is decreased. Thus, a nitride semiconductor light emitting device with small series resistance and capable of low voltage operation can be realized.

A method for fabricating a nitride semiconductor light emitting device according to the present invention includes the steps of: (a) epitaxially growing an alloy crystal layer of InₓAl_{y}Ga_{1-x-y}N (0<x<1, 0<y<1, 0<x+y<1) on a substrate to have n-type conductivity; (b) epitaxially growing a pn junction structure on the alloy crystal layer to be in contact with the alloy crystal layer, the pn junction structure including an active layer, a p-type semiconductor layer, and an n-type semiconductor layer; and (c) forming an ohmic electrode to be in contact with the alloy crystal layer.

According to the nitride semiconductor light emitting device fabrication method of the present invention, the alloy crystal layer is formed of InₓAl_{y}Ga_{1-x-y}N to have n-type conductivity. Therefore, according to the above-described knowledge, the contact resistance between the alloy crystal layer and the ohmic electrode which is in contact therewith is reduced. Thus, a nitride semiconductor light emitting device with smaller series resistance and low operation voltage can be realized.

In the nitride semiconductor light emitting device fabrication method of the present invention, step (a) includes forming an underlying layer of a first III-V nitride semiconductor on the substrate before the formation of the alloy crystal layer; and the alloy crystal layer is epitaxially grown to be lattice-matched with the underlying layer.

With the above feature, the alloy crystal layer lattice-matched with the underlying layer can be formed thick without occurrence of cracks. For example, when a p-side ohmic electrode and an n-side ohmic electrode are formed on one surface, the series resistance around the n-side ohmic electrode is further reduced. Thus, the operation voltage can be decreased.

Preferably, the nitride semiconductor light emitting device fabrication method of the present invention further includes the steps of: (d) separating the alloy crystal layer and the pn junction structure from the substrate; (e) forming a metal electrode on the p-type semiconductor layer of the pn junction structure, the reflectance of the metal electrode at a wavelength of light emitted from the active layer being higher than 70%; and (f) forming a metal film to be in contact with the metal electrode and have a thickness of 10 μm or more.

With the above feature, the light extraction efficiency improves. The metal film having a thickness of 10 μm or more, which is in contact with the metal electrode, improves the heat radiation property. Thus, a light emitting diode capable of highly efficient emission and high power operation can be realized.

In this case, preferably, step (a) includes forming a semiconductor layer of a second III-V nitride semiconductor on the substrate to be in contact with the substrate before the formation of the alloy crystal layer; and in step (d), the separation from the substrate is carried out by irradiating a surface of the substrate opposite to the semiconductor layer with light which has a wavelength absorbed by the semiconductor layer to decompose the semiconductor layer.

By decomposing the semiconductor layer in such a way, the stress in the semiconductor layer is relaxed. Due to the relaxation of the stress, occurrence of cracks inside the pn junction structure is suppressed. Therefore, even in the case of a substrate (wafer) having a relatively large area, the pn junction structure (epitaxially grown layers) can be separated with excellent repeatability without causing cracks.

In this case, preferably, the substrate is formed of sapphire, MgO, or LiGaᵤAl₁₋ᵤO₂ (0≦u≦1); and the semiconductor layer is formed of GaN, InₓAl_{y}Ga_{1-x-y}N (0<x<1, 0<y<1, 0<x+y<1), or ZnO.

With the above feature, a nitride semiconductor layer of GaN, InGaN, AlGaN, or the like, which has excellent crystallinity, can be epitaxially grown on the principal surface of the substrate. Further, in the case where the substrate is separated by irradiation with, for example, third harmonic light at 355 nm from a Nd:YAG laser, the nitride semiconductor layers having excellent crystallinity can readily be separated from the substrate because GaN, InₓGa₁₋ₓN (0<x≦1) or ZnO absorbs the laser light at 355 nm to be readily decomposed.

In the case where light is used for separation of the substrate, a light source of the light is preferably laser light which oscillates in a pulsed manner or emission lines of a mercury lamp.

When the laser light which oscillates in a pulsed manner is used, the power of light can be extremely increased, and therefore, separation of the nitride semiconductor layers grown on the substrate is readily separated. When the emission lines of a mercury lamp are used, the spot size is larger than that of the laser light although the light power is small as compared with the laser light. Therefore, the throughput in the light irradiation step is improved.

In the case of separating the substrate, the nitride semiconductor light emitting device fabrication method of the present invention preferably further includes, between step (b) and step (d), step (g) of adhering a supporting material to the pn junction structure, the supporting material being made of a material different from III-V nitride semiconductors.

With the above feature, handling of the pn junction structure from which the substrate is removed becomes easy.

In this case, the method may further include, after step (d), step (h) of separating the supporting material from the pn junction structure. For example, when a polymer film having no conductivity is used as the supporting material, the supporting material is preferably removed from the pn junction structure.

### BRIEF DESCRIPTION OF THE DRAWINGS

FIG. 1A shows a cross-sectional structure of a light emitting diode according to embodiment 1 of the present invention.

FIG. 1B is a band diagram of the principal part of the light emitting diode according to embodiment 1 of the present invention.

FIG. 2 is a graph illustrating the relationship between the composition ratio of Al (y) to In (x) and the strain in a quaternary alloy crystal layer (contact layer) of InAlGaN according to embodiment 1 of the present invention.

FIG. 3A shows a cross-sectional structure of a light emitting diode according to embodiment 2 of the present invention.

FIG. 3B is a band diagram of the principal part of the light emitting diode according to embodiment 2 of the present invention.

FIG. 4 shows a cross-sectional structure of a light emitting diode according to embodiment 3 of the present invention.

FIG. 5A through FIG. 5F are cross-sectional views illustrating the steps of a fabrication method of the light emitting diode according to embodiment 3 of the present invention.

FIG. 6 shows a cross-sectional structure of a semiconductor laser diode according to embodiment 4 of the present invention.

FIG. 7 shows a cross-sectional structure of a semiconductor laser diode according to embodiment 5 of the present invention.

FIG. 8 shows a cross-sectional structure of a semiconductor laser diode according to embodiment 6 of the present invention.

FIG. 9 shows a cross-sectional structure of a conventional light emitting diode.

### DESCRIPTION OF THE PREFERRED EMBODIMENTS

### Embodiment 1

Embodiment 1 of the present invention is described with reference to the drawings.

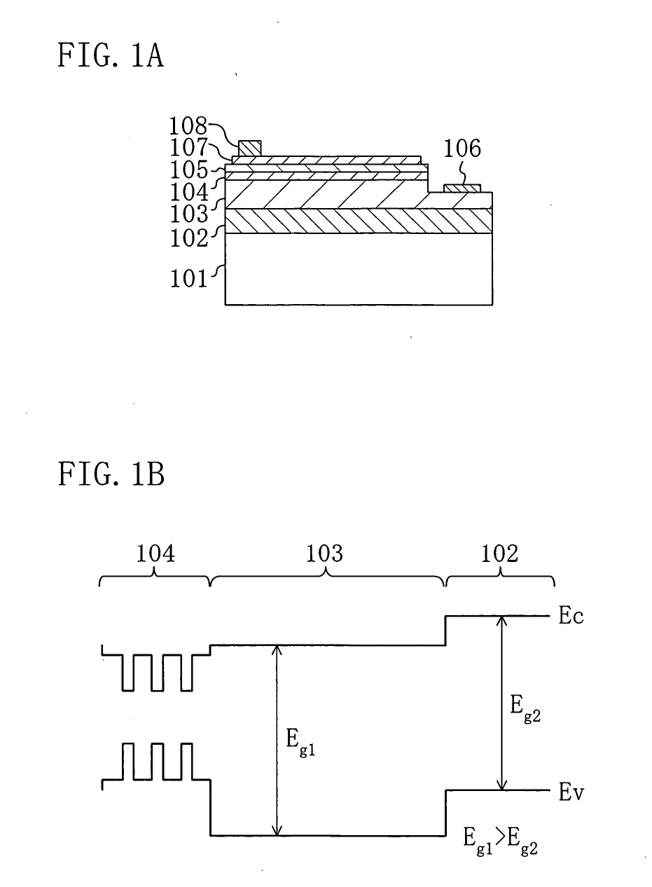

FIG. 1A shows a cross-sectional structure of a light emitting diode which is a nitride semiconductor light emitting device according to embodiment 1 of the present invention. FIG. 1B is a band diagram of electron energy in an active layer and a portion underlying the active layer in the light emitting device.

The structure of the light emitting diode and a fabrication method thereof according to embodiment 1 are described with reference to FIG. 1A.

First, for example, an underlying layer 102 of n-type GaN having a thickness of 2 μm, an n-type contact layer 103 of n-type InAlGaN (quaternary alloy crystal) having a thickness of 100 nm, a multiquantum well (MQW) active layer 104 of InGaN, and a p-type cladding layer 105 of p-type Al_{0.1}Ga_{0.9}N having a thickness of 0.1 μm are sequentially epitaxially grown over the principal surface of a substrate 101 of sapphire (monocrystal Al₂O₃) by, for example, MOCVD. Herein, the n-type contact layer 103 also functions as an n-type cladding layer which enables injected electrons and emitted light to be readily confined in the MQW active layer 104. The MQW active layer 104 includes three well layers, each of which is formed of In_{0.35}Ga_{0.65}N and has a thickness of 3 nm, and a barrier layer formed of GaN having a thickness of 10 nm.

Among organic metal materials, an example of the gallium (Ga) source is trimethylgallium (TMG), an example of the aluminum (Al) source is trimethylaluminum (TMA), and an example of the indium (In) source is trimethylindium (TMI). The nitride (N) source is ammonia (NH₃). An example of the n-type dopant source used is monosilane (SiH₄) which contains silicon (Si), and an example of the p-type dopant source used is cyclopentadienylmagnesium (Cp₂Mg) which contains magnesium (Mg).

Then, dry etching with chlorine (Cl₂) gas, for example, is selectively carried out on the formed p-type cladding layer 105, the MQW active layer 104 and the n-type contact layer 103, such that a portion of the n-type contact layer 103 is exposed.

Then, on the exposed surface of the n-type contact layer 103, an n-side electrode 106 is selectively formed of titanium (Ti), aluminum (Al), nickel (Ni) and gold (Au) subsequently from the substrate side, by sputtering, vacuum deposition, or the like, to have ohmic characteristics.

Then, on the upper surface of the p-type cladding layer 105, Ni and Au films are sequentially formed from the substrate side to form a layered structure having a thickness of about 10 nm. This layered structure constitutes a transparent electrode 107. Then, a p-side electrode 108 is formed of Au on a portion of the transparent electrode 107. The p-side electrode 108 functions as a bonding pad. It should be noted that the order of forming the n-side electrode 106, the transparent electrode 107 and the p-side electrode 108 is not limited to any particular order.

With the above structure, blue light emitted at, for example, 470 nm by recombination of electrons and holes in the MQW active layer 104 passes through the transparent electrode 107 to exit the light emitting device.

The MQW active layer 104 is capable of emitting light at, for example, about 340 nm to 550 nm by increasing or decreasing the In content in the InGaN well layers or by forming the layer 104 of quaternary alloy crystal of InAlGaN.

In embodiment 1, the n-type contact layer 103 is not only formed of quaternary alloy crystal of InAlGaN but also has a composition which is lattice-matched with the GaN underlying layer 102.

Herein, the lattice constant of InₓAl_{y}Ga_{1-x-y}N (0<x<1, 0<y<1, 0<x+y<1) of the n-type contact layer 103 is expressed by Formula 1 as shown below if it is determined by linear interpolation:
a=x·a_{InN}+y·a_{AlN}+(1−x−y)·a_{GaN} [Formula 1]
where a_{InN}, a_{AlN} and a_{GaN} are the lattice constants of InN, AlN and GaN. Specifically, a_{InN}=3.548 Å, a_{AlN}=3.112 Å, and a_{GaN}=3.189 Å.

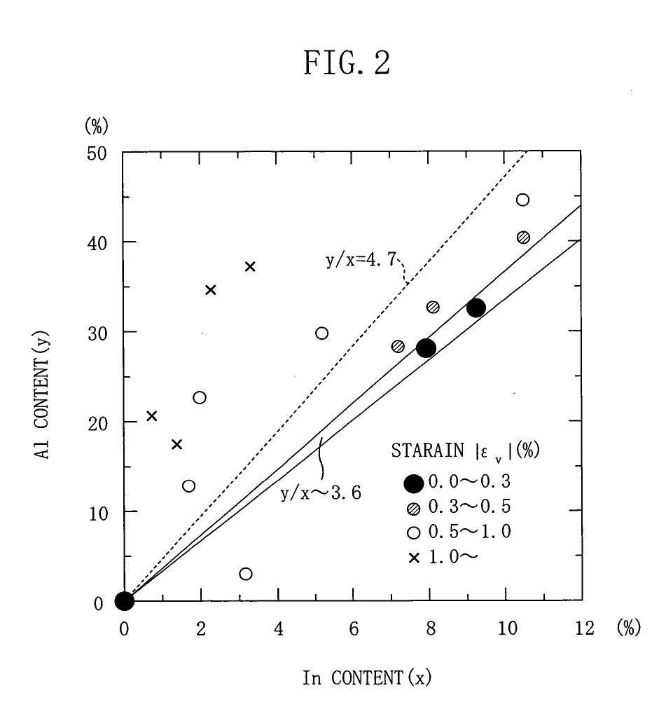

If the lattice constant of InₓAl_{y}Ga_{1-x-y}N is equal to the lattice constant of GaN, i.e., 3.189 Å, the relationship between the In content, x, and the Al content, y, is expressed by Formula 2 as shown below:
y=4.662x [Formula 2]
The present inventors actually formed various samples where an alloy crystal layer of InAlGaN was epitaxially grown at different composition ratios on a GaN layer and measured the strain of the alloy crystal layer in each sample. The result of the measurement is shown in FIG. 2. The composition of the grown alloy crystal layer was measured by Electron probe Micro-Analysis (PMA). The strain in the alloy crystal layer was calculated by evaluating a deviation in lattice constant based on X-ray diffraction pattern and reciprocal lattice mapping. As seen from FIG. 2, the present inventors found that a composition ratio of the alloy crystal with which the strain is near 0 is closer to a composition ratio satisfying the relationship of Formula 3 than to a composition ratio satisfying the relationship of Formula 2.
y=3.6x [Formula 3]

It should be noted that the n-type InAlGaN layer determined by Formula 3 is useful because it can realize a low contact resistance irrespective of its crystallinity not only when used in a semiconductor light emitting device but also when it is used as an n-type contact layer in other electronic devices, e.g., a field effect transistor.

The n-type contact layer 103 shown in FIG. 1A has a composition ratio of In_{0.09}Al_{0.33}Ga_{0.58}N which achieves a lattice match substantially under the condition of Formula 3. The present inventors confirmed that the energy gap of the n-type contact layer 103 is 3.46 eV from a result of an evaluation by a cathode luminescence method, and the like.

The energy gap of the quaternary alloy crystal of InAlGaN, E_{g}, is generally expressed by Formula 4:
E_{g}=x·E_{g}_{_{—}}_{InN}+y·E_{g}_{_{—}}_{AlN}+(1−x−y)·E_{g}_{_{—}}_{GaN}−c·(1−x−y)−c′·y·(1−x−y) [Formula 4]
where E_{g}_{_{—}}_{InN} is the energy gap of InN, E_{g}_{_{—}}_{AlN} is the energy gap of AlN, and E_{g}_{_{—}}_{GaN} is the energy gap of GaN, and c and c′ are so-called bowing parameters.

Since the energy gap of In_{0.09}Al_{0.33}Ga_{0.58}N is 3.46 eV, c=c′=2.6 eV. Thus, it is understood that, even if the In content and the Al content are increased, the energy gap of the quaternary alloy crystal, E_{g}, does not much increase.

The n-type contact layer 103 is doped with an n-type dopant of Si at a high concentration of, for example, 1×10¹⁸ cm⁻³ or more. With this and above features, the contact resistance between the n-type contact layer 103 and the n-side electrode 106 which is in contact with the n-type contact layer 103 results in an extremely small value of 1×10⁻⁶ Ωcm² or less.

In a comparative sample where the n-side electrode 106 was formed on an n-type GaN layer which was doped with Si at substantially the same concentration as the n-type contact layer 103, the contact resistance remained at about 5×10⁻⁵ Ωcm². It is understood that, in this case, the contact resistance is greatly decreased by forming the n-side electrode 106, which is an ohmic electrode, on the n-type contact layer 103 of In_{0.09}Al_{0.33}Ga_{0.58}N as in embodiment 1.

The energy gap of the n-type contact layer 103 of embodiment 1 is 3.46 eV, which is larger than that of gallium nitride (GaN), i.e., 3.4 eV. Nevertheless, considering that the ohmic contact resistance is greatly decreased, it is understood that the electron affinity of the n-type contact layer 103 of InAlGaN was increased, and the potential barrier produced by the difference between the work function (=electron affinity) of the n-side electrode 106 and the electron affinity of the n-type contact layer 103 was decreased.

FIG. 1B is a band diagram of electron energy in which the above circumstances are considered. Specifically, FIG. 1B schematically shows a band diagram of the MQW active layer 104 and a portion underlying the MQW active layer 104 in the light emitting device of embodiment 1. As shown in FIG. 1B, it is understood that the electron energy decreased at the lower end of conduction band Ec in the n-type InAlGaN contact layer 103, and as a result, the ohmic contact resistance decreased.

As described above, according to embodiment 1, in a nitride semiconductor light emitting device, i.e., a light emitting diode, the composition of the n-type contact layer 103 which is in contact with the n-side electrode (ohmic electrode) 106 is a quaternary alloy crystal of InAlGaN. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the light emitting diode can be decreased.

### Embodiment 2

Hereinafter, embodiment 2 of the present invention is described with reference to the drawings.

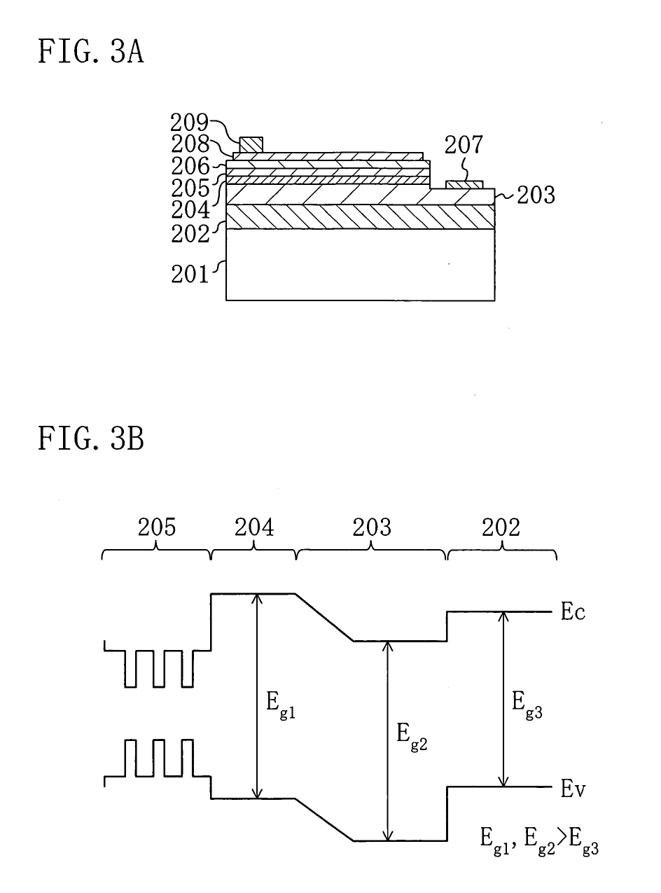

FIG. 3A shows a cross-sectional structure of a light emitting diode which is a nitride semiconductor light emitting device according to embodiment 2 of the present invention. FIG. 3B is a band diagram of electron energy in an active layer and a portion underlying the active layer in the light emitting device.

The structure of the light emitting diode and a fabrication method thereof according to embodiment 2 are described with reference to FIG. 3A.

First, for example, an underlying layer 202 of n-type GaN having a thickness of 2 μm, an n-type contact layer 203 of n-type InAlGaN (quaternary alloy crystal) having a thickness of 100 nm, an n-type cladding layer 204 of n-type Al_{0.1}Ga_{0.9}N having a thickness of 0.5 μm, a MQW active layer 205 of InGaN, and a p-type cladding layer 206 of p-type Al_{0.1}Ga_{0.9}N having a thickness of 0.1 μm are sequentially epitaxially grown over the principal surface of a substrate 201 of sapphire by, for example, MOCVD. Herein, the MQW active layer 205 includes three well layers, each of which is formed of In_{0.35}Ga_{0.65}N and has a thickness of 3 nm, and a barrier layer formed of GaN having a thickness of 10 nm.

Then, dry etching with chlorine (Cl₂) gas, for example, is selectively carried out on the formed p-type cladding layer 206, the MQW active layer 205, the n-type cladding layer 204 and the n-type contact layer 203, such that a portion of the n-type contact layer 203 is exposed.

Then, on the exposed surface of the n-type contact layer 203, an n-side electrode 207 is selectively formed of Ti, Al, Ni and Au sequentially from the substrate side, by sputtering, vacuum deposition, electron beam deposition, or the like, to have ohmic characteristics.

Then, on the upper surface of the p-type cladding layer 206, Ni and Au films are sequentially formed from the substrate side to form a layered structure having a thickness of about 10 nm. This layered structure constitutes a transparent electrode 208. Then, a p-side electrode 209 is formed of Au on a portion of the transparent electrode 208. The p-side electrode 209 functions as a bonding pad. It should be noted that the order of forming the n-side electrode 207, the transparent electrode 208 and the p-side electrode 209 is not limited to any particular order.

With the above structure, blue light emitted at, for example, 470 nm by recombination of electrons and holes in the MQW active layer 205 passes through the transparent electrode 208 to exit the light emitting device.

According to embodiment 2, the composition of the n-type contact layer 203 is In_{0.09}Al_{0.33}Ga_{0.58}N, which is the same as that of the n-type contact layer 103 of embodiment 1.

In embodiment 2, since the energy gap of the n-type cladding layer 204 of n-type Al_{0.1}Ga_{0.9}N is 3.59 eV, the n-type contact layer 203 of n-type In_{0.09}Al_{0.33}Ga_{0.58}N is adjusted in a stepwise or gradual fashion such that the energy gap of 0.13 eV between the n-type contact layer 203 and the n-type cladding layer 204 is increased to 3.59 eV at the interface between the n-type contact layer 203 and the n-type cladding layer 204, whereby the hetero barrier (potential barrier caused by hetero junction) is relaxed. That is, the n-type contact layer 203 includes a composition gradient region at and near the interface between the n-type contact layer 203 and the n-type cladding layer 204. With this region, no potential barrier occurs at the interface between the n-type contact layer 203 and the n-type cladding layer 204, and the series resistance is further reduced.

Although in the above example of embodiment 2 the n-type contact layer 203 includes a composition gradient region near the interface between the n-type contact layer 203 and the n-type cladding layer 204, alternatively, the n-type cladding layer 204 may include a composition gradient region near the interface between the n-type cladding layer 204 and the n-type contact layer 203 such that no potential barrier occurs at the interface between the n-type cladding layer 204 and the n-type contact layer 203. In the case where the n-type cladding layer 204 includes a composition gradient region, the composition of the n-type cladding layer 204 is preferably Al_{0.04}Ga_{0.96}N such that the energy gap is 3.46 eV at the interface between the n-type cladding layer 204 and the n-type contact layer 203.

The n-type contact layer 203 is doped with an n-type dopant of Si at a high concentration of, for example, 1×10¹⁸ cm⁻³ or more. Therefore, the contact resistance between the n-type contact layer 203 and the n-side electrode 207 which is in contact with the n-type contact layer 203 results in an extremely small value of 1×10⁻⁶ Ωcm² or less.

FIG. 3B is a band diagram of electron energy in which a large electron affinity and composition gradient region of the n-type In_{0.09}Al_{0.33}Ga_{0.58}N contact layer 203 in the light emitting diode of embodiment 2 are considered. Specifically, FIG. 3B schematically shows a band diagram of the MQW active layer 205 and a portion underlying the MQW active layer 205 in the light emitting device of embodiment 2. As shown in FIG. 3B, the electron energy decreases at the lower end of conduction band Ec in a portion of the n-type InAlGaN contact layer 203 near the n-type GaN layer 202.

As described above, according to embodiment 2, in a nitride semiconductor light emitting device, i.e., a light emitting diode, the composition of the n-type contact layer 203 which is in contact with the n-side electrode (ohmic electrode) 207 is a quaternary alloy crystal of InAlGaN. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the light emitting diode can be decreased.

### Embodiment 3

Hereinafter, embodiment 3 of the present invention is described with reference to the drawings.

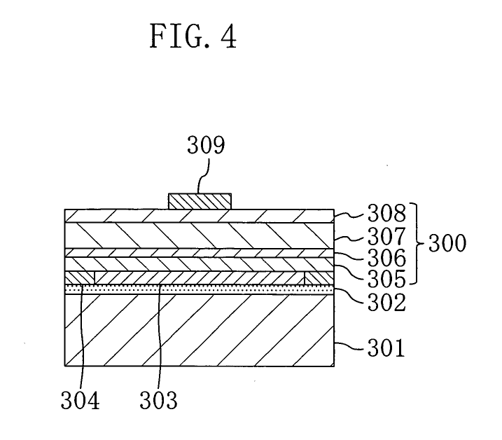

FIG. 4 shows a cross-sectional structure of a light emitting diode which is a nitride semiconductor light emitting device according to embodiment 3 of the present invention.

Referring to FIG. 4, the light emitting diode of embodiment 3 sequentially includes a p-type cladding layer 305 of p-type Al_{0.1}Ga_{0.9}N having a thickness of 0.1 μm, a MQW active layer 306 of InGaN, an n-type cladding layer 307 of n-type Al_{0.1}Ga_{0.9}N having a thickness of 0.5 μm, and an n-type contact layer 308 of n-type InAlGaN (quaternary alloy crystal) having a thickness of 100 nm. Herein, the MQW active layer 306 includes three well layers, each of which is formed of In_{0.35}Ga_{0.65}N and has a thickness of 3 nm, and a barrier layer formed of GaN having a thickness of 10 nm. The p-type cladding layer 305, the MQW active layer 306, the n-type cladding layer 307 and the n-type contact layer 308 constitutes a pn junction structure 300 including the MQW active layer 306. It should be noted that epitaxial growth of the pn junction structure 300 is started from the n-type contact layer 308 as will be described later.

On a part of the n-type contact layer 308, an n-side electrode 309 is selectively formed of Ti, Al, Ni and Au sequentially from the n-type contact layer 308 side to have ohmic characteristics.

On a surface of the p-type cladding layer 305 opposite to the MQW active layer 306, an insulating film 304 of silicon oxide (SiO₂) having a thickness of about 400 nm is provided. The insulating film 304 has an opening in which the side end surface of the insulating film 304 is exposed. The opening of the insulating film 304 is filled with a high reflection electrode 303 of platinum (Pt).

On a surface of the insulating film 304 and high reflection electrode 303 opposite to the p-type cladding layer 305 is an underlying metal film 302 formed of Ti and Au to have a layered structure. On the underlying metal film 302, a plating layer 301 formed of Au having a thickness of about 50 μm is provided.

With the above structure, blue light emitted at, for example, 470 nm by recombination of electrons and holes in the MQW active layer 306 is reflected by the high reflection electrode 303 and passes through a portion of the n-type contact layer 308 on which the n-side electrode 309 is not provided to exit the light emitting device.

As in embodiment 2, the n-type contact layer 308 is formed of In_{0.09}Al_{0.33}Ga_{0.58}N. Further, the n-type contact layer 308 includes a composition gradient region at and near the interface between the n-type contact layer 308 and the n-type Al_{0.1}Ga_{0.9}N cladding layer 307 such that the energy gap of 0.13 eV between the n-type contact layer 308 and the n-type cladding layer 307 is adjusted in a stepwise or gradual fashion to relax the hetero barrier. With this region, no potential barrier occurs between the n-type cladding layer 307 and the n-type contact layer 308, and therefore, a light emitting diode with a reduced series resistance is realized.

Although in the above example of embodiment 3 the n-type contact layer 308 includes a composition gradient region near the interface between the n-type contact layer 308 and the n-type cladding layer 307, alternatively, the n-type cladding layer 307 may include a composition gradient region near the interface between the n-type cladding layer 307 and the n-type contact layer 308 such that no potential barrier occurs at the interface between the n-type cladding layer 307 and the n-type contact layer 308. In the case where the n-type cladding layer 307 includes a composition gradient region, the composition of the n-type cladding layer 307 is preferably Al_{0.04}Ga_{0.96}N such that the energy gap is 3.46 eV at the interface between the n-type cladding layer 307 and the n-type contact layer 308.

The high reflection electrode 303 of Pt has a high reflectance of about 73% in visible and UV ranges. Therefore, a metal other than platinum (Pt), such as silver (Ag) having a reflectance of, for example, about 97%, rhodium (Rh) having a reflectance of, for example, about 84%, or the like, may be used instead so long as the high reflection electrode 303 has a large work function and exhibits relatively excellent ohmic characteristics as compared with the p-type cladding layer 305.

As described above, according to embodiment 2, in a nitride semiconductor light emitting diode, the composition of the n-type contact layer 308 which is in contact with the n-side electrode (ohmic electrode) 309 is a quaternary alloy crystal of InAlGaN as in embodiment 1. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the light emitting diode can be decreased.

The high reflection electrode 303 having a reflectance of 70% or higher is provided on a surface of the p-type cladding layer 305 opposite to the MQW active layer 306. With this structure, the light emitted by the MQW active layer 306 is reflected by the high reflection electrode 303 and then transmitted through the n-type contact layer 308 to exits the light emitting device. Therefore, the light extraction efficiency is greatly improved.

The plating layer 301 of Au is provided over a surface of the high reflection electrode 303 opposite to the p-type cladding layer 305 with the underlying metal film 302 interposed therebetween. With this structure, heat generated by the MQW active layer 306 is diffused through the plating layer 301. As a result, the heat radiation property of the light emitting device is improved, and accordingly, a high power operation is possible. Furthermore, since the light emitting device of embodiment 3 does not include an insulative substrate of sapphire, or the like, the electrostatic withstand voltage of the light emitting device is improved.

Hereinafter, a method for fabricating the light emitting diode which has the above structure is described with reference to the drawings.

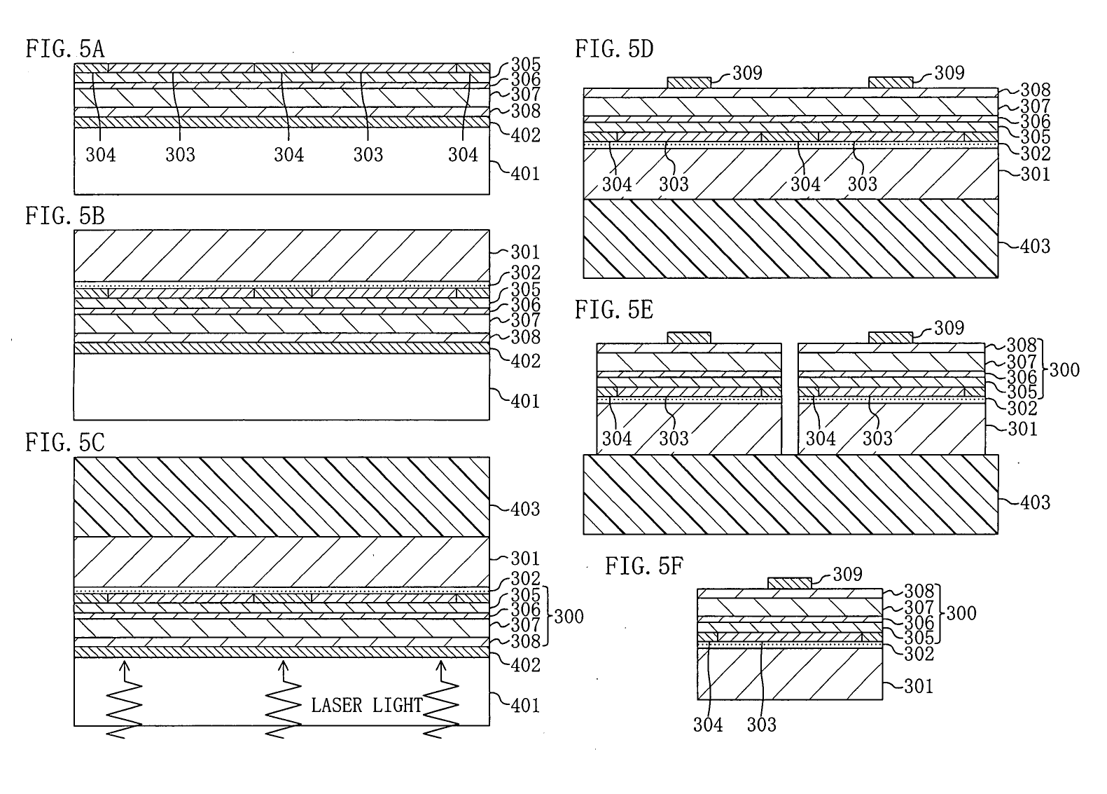

FIG. 5A through FIG. 5F are cross-sectional views illustrating the steps of the light emitting diode fabrication method according to embodiment 3 of the present invention.

Referring to FIG. 5A, first, an underlying layer 402 of n-type GaN, an n-type contact layer 308 of n-type InAlGaN (quaternary alloy crystal), an n-type cladding layer 307 of n-type Al_{0.1}Ga_{0.9}N, a MQW active layer 306 of InGaN, and a p-type cladding layer 305 of p-type Al_{0.1}Ga_{0.9}N are sequentially epitaxially grown over the principal surface of a substrate 401 of sapphire by, for example, MOCVD.

Then, an insulating film 304 is formed of SiO₂ by, for example, chemical vapor deposition (CVD) over the entire surface of the p-type cladding layer 305 so as to have a thickness of 400 nm. Thereafter, a resist pattern (not shown) is lithographically formed so as to have a plurality of openings in corresponding regions of the insulating film 304 in which a high reflection electrode is to be formed. The formed resist pattern is used as a mask to perform etching on the insulating film 304 such that the insulating film 304 has a plurality of openings through which the p-type cladding layer 305 is partially exposed. In the insulating film 304, each of the openings constitutes one electrode formation region. Subsequently, a Pt film is formed over the resist pattern and on the p-type cladding layer 305 exposed through the openings by, for example, electron beam deposition. Thereafter, a so-called lift-off process is carried out to remove the resist pattern and the Pt film formed thereon, whereby a high reflection electrode 303 of Pt is formed on the p-type cladding layer 305 exposed through the openings of the insulating film 304.

Herein, for the purpose of further reducing the contact resistance of the p-type cladding layer 305 with respect to the high reflection electrode 303, an n-type contact layer of p⁺ GaN to which Mg is added at about 1×10²¹ cm⁻³, for example, may be formed on the p-type cladding layer 305.

Then, referring to FIG. 5B, an underlying metal film 302 having a layered structure of Ti and Au films is formed on the high reflection electrode 303 and the insulating film 304 by electron beam deposition so as to have a thickness of about 200 nm. Thereafter, a plating layer 301 is formed of Au by plating so as to have a thickness of about 50 μm. Herein, the plating layer 301 only needs to have a thickness of 10 μm or more.

Then, referring to FIG. 5C, a supporting material 403 of a polymer film having a thickness of about 100 μm is provided over a surface of the plating layer 301 opposite to the underlying metal film 302. Herein, the polymer film used as the supporting material 403 is made of, for example, polyester and adhered to the plating layer 301 through an adhesive layer, which is foamable by heat to decrease or lose adhesiveness. Then, a surface of the substrate 401 opposite to the underlying layer 402 is irradiated with third harmonic light at 355 nm from a Nd (neodymium):YAG (yttrium aluminum garnet) laser in a manner such that the substrate surface is scanned with the laser light. The laser light is not absorbed by the sapphire substrate 401 but absorbed only by the n-type GaN underlying layer 402 because of its wavelength. Thus, heat is locally generated only in a portion of the underlying layer 402 which is irradiated with the laser light, and the generated heat thermally decomposes a part of the underlying layer 402 near the interface between the underlying layer 402 and the substrate 401. Specifically, GaN is thermally decomposed into nitrogen (N₂) gas and metal gallium (Ga). The metal Ga is then removed using an acid solution of hydrochloric acid (HCl), or the like, whereby the substrate 401 is readily separated from the pn junction structure 300. As a result, the pn junction structure 300, which is to be used as a light emitting diode, is formed on the plating layer 301 to obtain a device structure where the n-type contact layer 308 is exposed on the upper surface.

It should be noted that the light source for irradiation of the underlying layer 402 may be a KrF excimer laser at 248 nm or emission lines of a mercury lamp at 365 nm instead of the third harmonic light of the Nd:YAG laser.

The method for separating the substrate 401 from the pn junction structure 300 may be grinding of the substrate 401 instead of irradiation with light.

Then, referring to FIG. 5D, an n-side electrode (ohmic electrode) 309 is formed on the n-type contact layer 308 exposed by separation of the substrate 401 by, for example, electron beam deposition and a lift-off method.

Then, referring to FIG. 5E, the pn junction structure 300, which is an epitaxially-grown layered structure including a plurality of devices, is divided into square chips each having a size of 350 μm×350 μm. Specifically, the pn junction structure 300 is selectively etched using, for example, chlorine (Cl₂) gas in separatable regions such that the insulating film 304 is separated while the high reflection electrode 303 is kept unseparated inside each chip. Then, the underlying metal film 302 and the plating layer 301 are selectively removed using, for example, aqua regia (an acid solution containing concentrated hydrochloric acid and concentrated nitric acid at about 3:1), or the like. As a result, a plurality of light emitting diodes (chips) are uniformly arranged over the supporting material 403 to be adhered thereon. By heating the supporting material 403 to about 200° C., for example, the adhesive layer on the supporting material 403 of a polymer film is foamed by heat and substantially loses adhesiveness. Therefore, each light emitting diode can readily be removed from the supporting material 403. Thus, a single light emitting diode is obtained as shown in FIG. 5F.

Although the underlying layer 402 is formed of n-type GaN on the substrate 401 in the above example, but the underlying layer 402 is not limited to GaN. The underlying layer 402 may be formed of a III-V nitride compound semiconductor having any composition, such as AlGaN, InGaN, or the like, or may be formed of zinc oxide (ZnO) which is a II-VI oxide, so long as a portion of the underlying layer 402 absorbs the applied laser light.

The substrate 401 which does not absorb the aforementioned laser light may be formed of magnesium oxide (MgO) or LiGaᵤAl₁₋ᵤO₂ (0≦u≦1) instead of sapphire.

The supporting material 403 is not limited to a polymer film. For example, an so-called hetero-substrate which is of a different type from a III-V nitride semiconductor, such as silicon (Si), gallium arsenide (GaAs), indium phosphide (InP), gallium phosphide (GaP), copper tungsten (CuW), or the like, may be adhered over the plating layer 301 before or after irradiation with light. In this case, the hetero-substrate used as the supporting material 403 may not be separated from the light emitting diode chips in the step of FIG. 5E so long as the hetero-substrate has electrical conductivity.

### Embodiment 4

Hereinafter, embodiment 4 of the present invention is described with reference to the drawings.

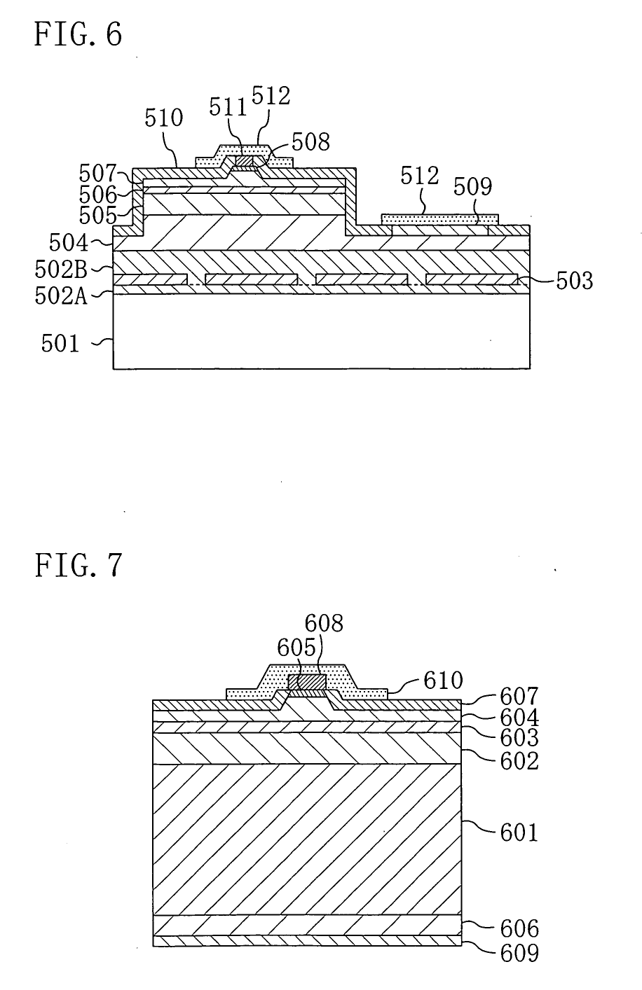

FIG. 6 shows a cross-sectional structure of a semiconductor laser diode which is a nitride semiconductor light emitting device according to embodiment 4 of the present invention.

Referring to FIG. 6, for example, a lower underlying layer 502A of n-type or undoped GaN having a thickness of 2 μm is provided on a substrate 501 of sapphire. A mask layer 503 of SiO₂ having a thickness of 100 nm is provided on the lower underlying layer 502A. The mask layer 503 has a striped opening pattern where the opening width is about 5 μm and the opening interval is about 10 μm. An upper underlying layer 502B of n-type or undoped GaN having a thickness of 2 μm is provided on the mask layer 503. The upper underlying layer 502B is selectively (laterally) grown from the lower underlying layer 502A which is exposed through the opening pattern of the mask layer 503. With this selective lateral growth, in a portion of the upper underlying layer 502B which is lying on the mask layer 503, the dislocation density of the lower underlying layer 502A on the order of 10¹⁹ cm⁻² is decreased to a value on the order of 10⁶ cm⁻².

The semiconductor laser diode includes, on the upper underlying layer 502B, an n-type contact layer 504 of n-type InAlGaN (quaternary alloy crystal) having a thickness of 100 nm, which includes a composition gradient region in the upper part, an n-type cladding layer 505 of n-type Al_{0.07}Ga_{0.93}N having a thickness of 1.2 μm, a MQW active layer 506 of InGaN, a p-type cladding layer 507 of p-type Al_{0.07}Ga_{0.93}N having a thickness of 0.5 μm, and a p-type contact layer 508 of p-type GaN having a thickness of 200 nm, which are sequentially epitaxially grown. Herein, the nitride semiconductor layers of n-type conductivity contain Si as a dopant, and the nitride semiconductor layers of p-type conductivity contain Mg as a dopant. The MQW active layer 506 includes three well layers, each of which is formed of In_{0.1}Ga_{0.9}N and has a thickness of 3 nm, and a barrier layer formed of GaN having a thickness of 7 nm. Further, the crystal growth conditions are optimized such that the MQW active layer 506 emits a blue-violet light at a wavelength of 405 nm.

The epitaxially grown layers are selectively removed to expose a portion of the n-type contact layer 504. On the exposed n-type contact layer 504, an n-side electrode 509 formed of Ti, Al, Ni and Au sequentially from the substrate 501 side and having ohmic characteristics is provided.

The p-type contact layer 508 and the upper part of the p-type cladding layer 507 have a stripe shape (ridge shape) whose width is about 2 μm. Herein, the striped part is provided in a region above the opening pattern of the mask layer 503, in which the dislocation density is small.

On the striped p-type contact layer 508, a p-side electrode 511 formed of Ti, Pt and Au sequentially from the substrate 501 side and having ohmic characteristics is provided.

On the exposed surface of the epitaxially grown layers except for the n-side electrode 509 and the p-side electrode 511, a protective insulating film 510 of SiO₂ having a thickness of 200 nm is provided. On each of the n-side electrode 509 and the p-side electrode 511, a pad electrode 512 formed of Ti and Au sequentially from the substrate 501 side is provided. Herein, the pad electrode 512 is formed on the p-side electrode 511 so as to cover the striped portion.

The striped portion functions as a waveguide for blue-violet laser light where the light emitted from the MQW active layer 506 is confined due to the difference in refractive index between the protective insulating film 510 and the p-type cladding layer 507. The striped waveguide is formed such that, for example, the length of the cavity, which extends in a direction perpendicular to the longitudinal direction of the waveguide (resonant direction of laser light), is 700 μm, and the facets face each other. One of the facets is coated with dielectric films to achieve high reflectance, whereby a blue-violet semiconductor laser structure is formed.

With the above structure, occurrence of a kink phenomenon in current-light power characteristic, which would be caused due to spatial hole burning during a high power operation, is suppressed, and a high power laser diode with a stable single lateral mode is realized.

A feature of embodiment 4 is that, as in embodiments 1 to 3, a portion of the n-type contact layer 504 which is in contact with the n-side electrode (ohmic electrode) 509 has a composition of In_{0.09}Al_{0.33}Ga_{0.58}N. Further, the n-type contact layer 504 includes a composition gradient region at and near the interface between the n-type contact layer 504 and the n-type Al_{0.07}Ga_{0.93}N cladding layer 505 such that the energy gap of 0.07 eV between the n-type contact layer 504 and the n-type cladding layer 505 is adjusted in a stepwise or gradual fashion to relax the hetero barrier. With this region, no potential barrier occurs between the n-type cladding layer 505 and the n-type contact layer 504, and therefore, a light emitting diode with a reduced series resistance is realized.

Although in the above example of embodiment 4 the n-type contact layer 504 includes a composition gradient region near the interface between the n-type contact layer 504 and the n-type cladding layer 505, alternatively, the n-type cladding layer 505 may include a composition gradient region near the interface between the n-type cladding layer 505 and the n-type contact layer 504 such that no potential barrier occurs at the interface between the n-type cladding layer 505 and the n-type contact layer 504. In the case where the n-type cladding layer 505 includes a composition gradient region, the composition of the n-type cladding layer 505 is preferably Al_{0.04}Ga_{0.96}N such that the energy gap is 3.46 eV at the interface between the n-type cladding layer 505 and the n-type contact layer 504.

The n-type contact layer 504 is doped with an n-type dopant of Si at a high concentration of, for example, 1×10¹⁸ cm⁻³ or more. Therefore, the contact resistance between the n-type contact layer 504 and the n-side electrode 509 which is in contact with the n-type contact layer 504 results in an extremely small value of 1×10⁻⁶ Ωcm² or less.

As described above, according to embodiment 4, in a nitride semiconductor light emitting device, i.e., a semiconductor laser diode, the composition of the n-type contact layer 504 which is in contact with the n-side electrode (ohmic electrode) 509 is a quaternary alloy crystal of InAlGaN. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the semiconductor laser diode can be decreased. Thus, a long-life blue-violet semiconductor laser diode with reduced power consumption can be realized.

In the laser diode described in the above example of embodiment 4, over the sapphire substrate 501, a striped waveguide is formed above a low dislocation density region formed according to a selective lateral growth method. However, the substrate 501 may be formed of gallium nitride (GaN) in the absence of the lower underlying layer 502A, the mask layer 503 and the upper underlying layer 502B so long as the dislocation density on the order of 10⁶ cm⁻² is realized in the epitaxially grown layers including the n-type contact layer 504 and the layers grown thereon. Even when the substrate 501 is formed of sapphire, the dislocation density in the epitaxially grown layers may be decreased by providing a single underlying layer of aluminum nitride (AlN) having a relatively large thickness of about 1 μm.

In a blue-violet semiconductor laser diode according to embodiment 4, light guide layers of, for example, n-type GaN and p-type GaN may be provided between the MQW active layer 506 and the n-type cladding layer 505 and between the MQW active layer 506 and the p-type cladding layer 507, respectively, for improving the confinement efficiency of emitted light.

Further, a so-called electron blocking layer of, for example, p-type Al_{0.15}Ga_{0.85}N may be provided on the MQW active layer 506 for suppressing an overflow of electrons from the MQW active layer 506 toward the p-type semiconductor layer.

### Embodiment 5

Hereinafter, embodiment 5 of the present invention is described with reference to the drawings.

FIG. 7 shows a cross-sectional structure of a semiconductor laser diode which is a nitride semiconductor light emitting device according to embodiment 5 of the present invention.

The structure of the semiconductor laser diode and a fabrication method thereof according to embodiment 5 are described with reference to FIG. 7.

Referring to FIG. 7, first, an n-type cladding layer 602 of n-type Al_{0.07}Ga_{0.93}N having a thickness of 1.2 μm, a MQW active layer 603 of InGaN, a p-type cladding layer 604 of p-type Al_{0.07}Ga_{0.93}N having a thickness of 0.5 μm, and a p-type contact layer 605 of p-type GaN having a thickness of 200 nm are sequentially epitaxially grown over the principal surface of an n-type substrate 601 of n-type GaN by, for example, MOCVD. Herein, the MQW active layer 603 includes three well layers, each of which is formed of In_{0.1}Ga_{0.9}N and has a thickness of 3 nm, and a barrier layer formed of GaN having a thickness of 7 nm. Further, the crystal growth conditions are optimized such that the MQW active layer 603 emits blue-violet light at a wavelength of 405 nm.

Then, a surface of the n-type substrate 601 opposite to the n-type cladding layer 602 is ground such that the n-type substrate 601 is thinned to 150 μm or less (back surface grinding). Thereafter, over the ground surface of the n-type substrate 601 opposite to the n-type cladding layer 602, an n-type contact layer 606 is formed of n-type In_{0.09}Al_{0.33}Ga_{0.58}N (quaternary alloy crystal) having a thickness of 100 nm by MOCVD.

Then, as in embodiment 4, the p-type contact layer 605 and the upper part of the p-type cladding layer 604 are selectively etched to form a striped (ridge) portion having a width of, for example, about 2 μm. Subsequently, at both sides of the striped portion of the p-type cladding layer 604, a protective insulating film 607 is selectively formed of SiO₂ by CVD so as to have a thickness of 200 nm.

Then, on the p-type contact layer 605, a p-side electrode 608 is formed of Ni, Pt and Au sequentially from the substrate side by electron beam deposition, or the like, so as to have ohmic characteristics. Subsequently, a pad electrode 610 is formed of Ti and Au on the p-side electrode 608.

Then, on a surface of the n-type contact layer 606 opposite to the n-type substrate 601, an n-side electrode 609 is formed of Ti, Al, Ni and Au sequentially from the substrate side so as to have ohmic characteristics. It should be noted that the order of forming the p-side electrode 608 and the n-side electrode 609 is not limited to any particular order.

In embodiment 5, the contact resistance between the n-type contact layer 606 and the n-side electrode 609 which is in contact with the n-type contact layer 606 results in an extremely small value of 1×10⁻⁶ Ωcm² or less.

Then, facets are formed to face each other in a direction perpendicular to the longitudinal direction of the striped waveguide such that the waveguide functions as a cavity. Among the facets, the reflection facet is coated with a dielectric to have higher reflectance, whereby a semiconductor laser structure is obtained.

With the above structure, the light emitted from the MQW active layer 603 is confined due to the difference in refractive index between the protective insulating film 607 and the p-type cladding layer 604. Thus, occurrence of a kink phenomenon in current-light power characteristic is suppressed, and a high power laser diode with a stable single lateral mode is realized.

According to embodiment 5, in a nitride semiconductor light emitting device, i.e., a semiconductor laser diode, the composition of the n-type contact layer 606 which is in contact with the n-side electrode (ohmic electrode) 609 is a quaternary alloy crystal of InAlGaN as in embodiment 4. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the semiconductor laser diode can be decreased. Thus, a long-life blue-violet semiconductor laser diode with reduced power consumption can be realized.

In embodiment 5, the n-type substrate 601 is formed of n-type GaN. Therefore, it is not necessary to etch a part of the epitaxially grown layers during the formation of the n-side electrode 609, which would be necessary when the substrate is formed of, for example, insulative sapphire. Further, GaN is the same nitride semiconductor as the epitaxially grown layers while sapphire is not, and therefore, cleavage is readily carried out. Thus, the flatness and reflectance of the facets of the cavity are improved. As a result, a semiconductor laser diode capable of operating with a lower threshold current is realized. For example, if the n-type substrate 601 is formed of GaN, the dislocation density in the epitaxially grown layers can be on the order of 10⁶ cm⁻² or smaller, and therefore, the life of the laser diode can be further prolonged.

In a blue-violet semiconductor laser diode according to embodiment 5, light guide layers of, for example, n-type GaN and p-type GaN may be provided between the MQW active layer 603 and the n-type cladding layer 602 and between the MQW active layer 603 and the p-type cladding layer 604, respectively, for improving the confinement efficiency of emitted light.

Further, a so-called electron blocking layer of, for example, p-type Al_{0.15}Ga_{0.85}N may be provided on the MQW active layer 603 for suppressing an overflow of electrons from the MQW active layer 603 toward the p-type semiconductor layer.

### Embodiment 6

Hereinafter, embodiment 6 of the present invention is described with reference to the drawings.

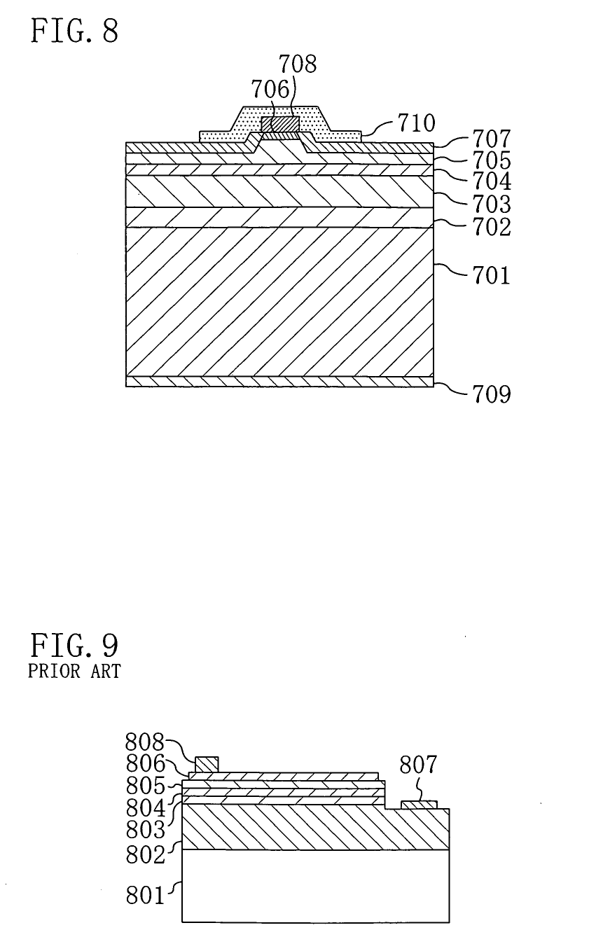

FIG. 8 shows a cross-sectional structure of a semiconductor laser diode which is a nitride semiconductor light emitting device according to embodiment 6 of the present invention.

Embodiment 6 is different from embodiment 5 in that the n-type substrate 601 formed of n-type GaN in embodiment 5 is formed of a quaternary alloy crystal of n-type InAlGaN instead and that a composition gradient layer formed of n-type InAlGaN is provided between the n-type InAlGaN substrate and an n-type AlGaN cladding layer.

The structure of the semiconductor laser diode and a fabrication method thereof according to embodiment 6 are described with reference to FIG. 8.

First, an n-type substrate 701 of n-type InAlGaN shown in FIG. 8 is prepared as described below.

For example, a buffer layer (not shown) of GaN having a thickness of about 200 nm and an n-type In_{0.09}Al_{0.33}Ga_{0.58}N layer which is lattice-matched with gallium nitride (GaN) as in embodiments 1 to 5 and has a thickness of 300 μm are formed on a sapphire substrate (not shown) using a Hydride Vapor Phase Epitaxy (HVPE) method. Specifically, In, Al and Ga are respectively put into boats, and then, hydrogen chloride (HCl) gas is supplied over each boat, whereby Group III source gases of indium chloride (InCl), aluminum chloride (AlCl) and gallium chloride (GaCl) are produced. The produced Group III source gases and ammonium (NH₃) gas containing a nitrogen source are used to carry out epitaxial growth at the substrate temperature of, for example, about 1000° C. An increase in flow rate of the Group III source gases enables a rapid growth at the growth rate of, for example, 50 μm/h or more. Herein, during the growth of the buffer layer, only GaCl of the Group III source gases is used. The doping with silicon (Si) as an n-type dopant uses monosilane gas (SiH₄).

Then, a surface of the sapphire substrate opposite to the n-type substrate 701 is irradiated with third harmonic light at 355 nm from a Nd:YAG laser. This irradiation with the laser light thermally decomposes GaN of the buffer layer at and near the interface between the buffer layer and the sapphire substrate. Thus, the n-type In_{0.09}Al_{0.33}Ga_{0.58}N layer is separated from the sapphire substrate, whereby the n-type substrate 701 of n-type In_{0.09}Al_{0.33}Ga_{0.58}N is obtained.

Then, after decomposition residuum of the buffer layer on the n-type substrate 701 is removed, a composition gradient layer 702 of n-type InAlGaN having a thickness of 100 nm, an n-type cladding layer 703 of n-type Al_{0.07}Ga_{0.93}N having a thickness of 1.2 μm, a MQW active layer 704 of InGaN, a p-type cladding layer 705 of p-type Al_{0.07}Ga_{0.93}N having a thickness of 0.5 μm, a p-type contact layer 706 of p-type GaN having a thickness of 200 nm are sequentially epitaxially grown over the n-type substrate 701 by, for example, MOCVD. Herein, the MQW active layer 704 includes three well layers, each of which is formed of In_{0.1}Ga_{0.9}N and has a thickness of 3 nm, and a barrier layer formed of GaN having a thickness of 7 nm. Further, the crystal growth conditions are optimized such that the MQW active layer 704 emits blue-violet light at a wavelength of 405 nm.

Then, as in embodiments 4 and 5, the p-type contact layer 706 and the upper part of the p-type cladding layer 705 are selectively etched to form a striped (ridge) portion having a width of, for example, about 2 μm. Subsequently, at both sides of the striped portion of the p-type cladding layer 705, a protective insulating film 707 is selectively formed of SiO₂ by CVD so as to have a thickness of 200 nm.

Then, on the p-type contact layer 706, a p-side electrode 708 is formed of Ni, Pt and Au sequentially from the n-type substrate 701 side by electron beam deposition, or the like, so as to have ohmic characteristics. Subsequently, a pad electrode 710 is formed of Ti and Au on the p-side electrode 708.

Then, a surface of the n-type substrate 701 opposite to the composition gradient layer 702 is ground such that the n-type substrate 701 is thinned to about 150 μm (back surface grinding). Thereafter, over the back surface of the thinned n-type substrate 701, an n-side electrode 709 is formed of Ti, Al, Ni and Au sequentially from the substrate side so as to have ohmic characteristics. With this structure, the contact resistance between the n-side electrode 709 and the n-type substrate 701 results in an extremely small value of 1×10⁻⁶ Ωcm² or less.

Then, facets are formed to face each other in a direction perpendicular to the longitudinal direction of the striped waveguide such that the waveguide functions as a cavity. Thereafter, one of the facets is coated with a dielectric to have higher reflectance, whereby a semiconductor laser structure is formed.

With the above structure, the light emitted from the MQW active layer 704 is confined due to the difference in refractive index between the protective insulating film 707 and the p-type cladding layer 705. As a result, occurrence of a kink phenomenon in current-light power characteristic is suppressed, and a high power laser diode with a stable single lateral mode is realized.

Since the bandgap of Al_{0.07}Ga_{0.93}N of the n-type cladding layer 703 is 3.53 eV, the composition gradient layer 702 of n-type InAlGaN is provided for adjusting the band gap of 0.07 eV between Al_{0.07}Ga_{0.93}N of the n-type cladding layer 703 and n-type In_{0.09}Al_{0.33}Ga_{0.58}N of the n-type substrate 701 in a stepwise or gradual fashion to relax the hetero barrier. With this structure, no potential barrier occurs between the n-type cladding layer 703 and the n-type substrate 701, and therefore, the series resistance is further reduced.

Although in the above example of embodiment 6 the composition gradient layer 702 is provided between the n-type substrate 701 and the n-type cladding layer 703, alternatively, instead of the composition gradient layer 702, a composition gradient region may be provided in a portion of the n-type cladding layer 703 near the interface between the n-type cladding layer 703 and the n-type substrate 701 such that no potential barrier occurs at the interface between the n-type cladding layer 703 and the n-type substrate 701. In the case where the composition gradient region is provided in a portion of the n-type cladding layer 703, the composition of the n-type cladding layer 703 is preferably Al_{0.04}Ga_{0.96}N such that the energy gap is 3.46 eV at the interface between the n-type cladding layer 703 and the n-type substrate 701.

As described above, according to embodiment 6, in a nitride semiconductor light emitting device, i.e., a semiconductor laser diode, the composition of the n-type substrate 701 which is in contact with the n-side electrode (ohmic electrode) 709 is a quaternary alloy crystal of InAlGaN. In this structure, the position of the lower end of the conduction band in InAlGaN is lower than that of GaN because the electron affinity of InAlGaN is greater than that of GaN. Therefore, the ohmic contact resistance is extremely small, and as a result, the series resistance and the operation voltage in the semiconductor laser diode can be decreased. Thus, a long-life blue-violet semiconductor laser diode with reduced power consumption can be realized.

In embodiment 6, the n-type substrate 701 is formed of n-type InAlGaN. Therefore, it is not necessary to etch a part of the epitaxially grown layers during the formation of the n-side electrode 709, which would be necessary when the substrate is formed of, for example, insulative sapphire. Further, InAlGaN is the same nitride semiconductor as the epitaxially grown layers while sapphire is not, and therefore, cleavage is readily carried out. Thus, the flatness and reflectance of the facets of the cavity are improved. As a result, a semiconductor laser diode capable of operating with a lower threshold current is realized.

In a blue-violet semiconductor laser diode according to embodiment 6, light guide layers of, for example, n-type GaN and p-type GaN may be provided between the MQW active layer 704 and the n-type cladding layer 703 and between the MQW active layer 704 and the p-type cladding layer 705, respectively, for improving the confinement efficiency of emitted light.

Further, a so-called electron blocking layer of, for example, p-type Al_{0.15}Ga_{0.85}N may be provided on the MQW active layer 704 for suppressing an overflow of electrons from the MQW active layer 704 toward the p-type semiconductor layer.

In embodiments 1 to 6, the principal surfaces of sapphire, GaN and InAlGaN used for the substrate for epitaxial growth may have any plane direction so long as a desired light emitting device is fabricated. For example, the principal surface may have (0001) plane, which is a typical plane direction, or may have a plane which is off-angled from (0001) plane, i.e., a plane slanted from (0001) plane by a certain angle. In a semiconductor laser diode application, the substrate may have any plane direction so long as cleavage can be carried out in a direction perpendicular to the longitudinal direction of the striped waveguide.

Examples of the substrate material other than sapphire and III-V nitrides, such as GaN, and the like, include MgO, LiGaO₂ and LiGaᵤAl₁₋ᵤO₂ (0≦u≦1). With any of these substrate materials, a nitride semiconductor, such as GaN, or the like, can be formed with excellent crystallinity. Further, in the case where the substrate is separated from the epitaxially grown layers by irradiating the substrate with third harmonic light at 355 nm from a Nd:YAG laser, the epitaxially grown layers of nitride semiconductors having excellent crystallinity can readily be separated from the substrate because GaN, InₓGa₁₋ₓN (0<x≦1) and ZnO absorb third harmonic light from a Nd:YAG laser to be readily decomposed.

The method for epitaxially growing nitride semiconductors is not limited to MOCVD. For example, a Molecular Beam Epitaxy (MBE) method or a HVPE method may be appropriately used according to the thickness or composition of each epitaxially grown layer.

As described above, a nitride semiconductor light emitting device and a fabrication method thereof according to the present invention enable a low-voltage operation and are useful to visible and UV-range light emitting diodes, semiconductor laser diodes for high density optical discs, etc.

What is claimed is:

1. A nitride semiconductor light emitting device, comprising:
an active layer formed of a first III-V nitride semiconductor, the active layer having opposite surfaces which face each other;
an alloy crystal layer formed of InₓAl_{y}Ga_{1-x-y}N (0<x<1, 0<y<1, 0<x+y<1) on one of the opposite surfaces of the active layer, the alloy crystal layer having n-type conductivity; and
an ohmic electrode formed to be in contact with the alloy crystal layer.

2. The nitride semiconductor light emitting device of claim 1, further comprising a substrate and an underlying layer formed of a second III-V nitride semiconductor on the substrate,
wherein the alloy crystal layer is lattice-matched with the underlying layer.

3. The nitride semiconductor light emitting device of claim 1, wherein in the alloy crystal layer, the composition ratio of y to x (y/x) in InₓAl_{y}Ga_{1-x-y}N (0<x<1, 0<y<1, 0<x+y<1) is in the range of 3.5 to 3.7.

4. The nitride semiconductor light emitting device of claim 1, wherein the ohmic electrode has a contact resistance of 1×10⁻⁶ Ωcm² or less.

5. The nitride semiconductor light emitting device of claim 1, further comprising a first cladding layer formed of Al_{z}Ga_{1-z}N (0<z≦1) to be in contact with the alloy crystal layer, the first cladding layer having n-type conductivity,
wherein in the composition of the alloy crystal layer, the content of Al, Ga or In is gradient such that a lower end of a conduction band is gradual at an interface between the alloy crystal layer and the first cladding layer.

6. The nitride semiconductor light emitting device of claim 1, further comprising a first cladding layer formed of Al_{z}Ga_{1-z}N (0<z≦1) to be in contact with the alloy crystal layer, the first cladding layer having n-type conductivity,
wherein in the composition of the first cladding layer, the content of Al is gradient such that a lower end of a conduction band is gradual at an interface between the first cladding layer and the alloy crystal layer.

7. The nitride semiconductor light emitting device of claim 1, further comprising:
a second cladding layer formed of a third III-V nitride semiconductor on the other surface of the active layer, the second cladding layer having p-type conductivity; and
a metal electrode formed to be in contact with the second cladding layer, the reflectance of the metal electrode at a wavelength of light emitted from the active layer being higher than 70%,
wherein the emitted light passes through the alloy crystal layer to exit the light emitting device.

8. The nitride semiconductor light emitting device of claim 7, wherein the metal electrode contains platinum (Pt), silver (Ag) or rhodium (Rh) as a main constituent.

9. The nitride semiconductor light emitting device of claim 7, further comprising a metal film formed to be in contact with the metal electrode and have a thickness of 10 μm or more.

10. The nitride semiconductor light emitting device of claim 9, wherein the metal film contains gold (Au) as a main constituent.

11. The nitride semiconductor light emitting device of claim 1, further comprising a second cladding layer formed of a third III-V nitride semiconductor on the other surface of the active layer, the second cladding layer having p-type conductivity,
wherein the second cladding layer has a striped structure which functions as a waveguide, the striped structure enabling the active layer to cause laser oscillation.

12. A nitride semiconductor light emitting device, comprising:
a substrate formed of GaN to have n-type conductivity;
a pn junction structure formed on a surface of the substrate, the pn junction structure including an active layer;
an alloy crystal layer formed of InₓAl_{y}Ga_{1-x-y}N (0<x<1, 0<y<1, 0<x+y<1) on the other surface of the substrate, the alloy crystal layer having n-type conductivity; and
an ohmic electrode formed to be in contact with the alloy crystal layer.

13. A nitride semiconductor light emitting device, comprising:
a substrate formed of InₓAl_{y}Ga_{1-x-y}N (0<x<1, 0<y<1, 0<x+y<1) to have n-type conductivity;
a pn junction structure formed to be in contact with the substrate, the pn junction structure including an active layer; and
an ohmic electrode formed to be in contact with the substrate.

14. A method for fabricating a nitride semiconductor light emitting device, comprising the steps of:
(a) epitaxially growing an alloy crystal layer of InₓAl_{y}Ga_{1-x-y}N (0<x<1, 0<y<1, 0<x+y<1) on a substrate to have n-type conductivity;
(b) epitaxially growing a pn junction structure on the alloy crystal layer to be in contact with the alloy crystal layer, the pn junction structure including an active layer, a p-type semiconductor layer, and an n-type semiconductor layer; and
(c) forming an ohmic electrode to be in contact with the alloy crystal layer.

15. The method of claim 14, wherein:
step (a) includes forming an underlying layer of a first III-V nitride semiconductor on the substrate before the formation of the alloy crystal layer; and
the alloy crystal layer is epitaxially grown to be lattice-matched with the underlying layer.

16. The method of claim 14, further comprising the steps of:
(d) separating the alloy crystal layer and the pn junction structure from the substrate;
(e) forming a metal electrode on the p-type semiconductor layer of the pn junction structure, the reflectance of the metal electrode at a wavelength of light emitted from the active layer being higher than 70%; and
(f) forming a metal film to be in contact with the metal electrode and have a thickness of 10 μm or more.

17. The method of claim 16, wherein:
step (a) includes forming a semiconductor layer of a second III-V nitride semiconductor on the substrate to be in contact with the substrate before the formation of the alloy crystal layer; and
in step (d), the separation from the substrate is carried out by irradiating a surface of the substrate opposite to the semiconductor layer with light which has a wavelength absorbed by the semiconductor layer to decompose the semiconductor layer.

18. The method of claim 17, wherein:
the substrate is formed of sapphire, MgO, or LiGaᵤAl₁₋ᵤO₂ (0≦u≦1); and
the semiconductor layer is formed of GaN, InₓAl_{y}Ga_{1-x-y}N (0<x<1, 0<y<1, 0<x+y<1), or ZnO.

19. The method of claim 17, wherein a light source of the light is laser light which oscillates in a pulsed manner or emission lines of a mercury lamp.

20. The method of claim 16, further comprising, between step (b) and step (d), step (g) of adhering a supporting material to the pn junction structure, the supporting material being made of a material different from III-V nitride semiconductors.

21. The method of claim 20, further comprising, after step (d), step (h) of separating the supporting material from the pn junction structure.
